(19) United States
(12) Patent Application Publication
(10) Pub. No.: US 2007/0026612 A1
(43) Pub. Date: Feb. 1, 2007

(54) Method of fabricating flash memory device having self-aligned floating gate

(75) Inventor: Young Bok Lee, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/434,435

(22) Filed: May 15, 2006

(30) Foreign Application Priority Data
Jul. 26, 2005 (KR) 2005-67689

(51) Int. Cl. H01L 21/336; H01L 21/3205

(52) U.S. Cl. 438/264; 438/257; 438/211; 438/593

(57) ABSTRACT

A method of fabricating a flash memory device having a self-aligned floating gate (SAFG) wherein a floating gate is formed by a SAFG process. After a dielectric layer is formed, the dielectric layer of a test pattern region is stripped and a control gate is formed so that the control gate and the floating gate are interconnected. Therefore, a test transistor can be formed even in the SAFG scheme.

### BACKGROUND

1. Field of the Invention

The invention relates to a method of fabricating a flash memory device. More particularly, the invention relates to a method of fabricating a flash memory device, wherein a test transistor for analyzing cell characteristics is formed in a self-aligned floating gate (SAFG) scheme.

2. Discussion of Related Art

Recently, as the size of components in NAND flash memory devices has been reduced, overlay margin has been reduced due the limitations of the application of a minimum design rule between the isolation layer and the floating gate and the mask resolution capability. This is very detrimental to same cell characteristics.

To overcome the problem, a self-aligned floating gate (SAFG) scheme in which the floating gate is formed in the isolation trench, which is already formed on the substrate, in a self-aligned way has been introduced.

In the flash cell, the floating gate serves as a memory that stores and erases electrons upon program and erase. Unlike a general transistor, the control gate is separated from the floating gate through an oxide nitride-oxide (ONO) layer. Accordingly, bias applied to the control gate is reduced as much as the coupling ratio by the ONO layer and is then transferred to the floating gate. It is thus difficult to confirm intrinsic cell characteristics.

To analyze the cell characteristics, a test transistor using the floating gate as an electrode is formed.

In the SAFG scheme, however, the floating gate is formed on the active region and the floating gate is automatically separated in the field region. Therefore, bias of a floating gate of a selected cell cannot be transferred to the floating gate of the test transistor.

Accordingly, it is impossible to form the test transistor and it is also difficult to analyze the intrinsic property. This makes it difficult to improve device characteristics.

### SUMMARY OF THE INVENTION

An embodiment of the invention relates to a method of fabricating a flash memory device having a SAFG, in which a test transistor used to analyze cell characteristics can be formed in a SAFG scheme.

A method of fabricating a flash memory device having a SAFG according to an aspect of the invention includes the steps of forming an isolation layer in a semiconductor substrate having a cell region and a test pattern region, defining an active region, and forming a first polysilicon layer, which is self-aligned with the isolation layer, on the active region with the tunnel oxide layer interposed therebetween; forming a dielectric layer and a capping polysilicon layer on the entire surface; stripping the capping polysilicon layer and the dielectric layer formed on the test pattern region; forming a second polysilicon layer on the entire surface; etching the second polysilicon layer and the capping polysilicon layer formed in the cell region using a control gate etch mask, forming a control gate, and etching the second polysilicon layer and the first polysilicon layer formed in the test pattern region, forming a gate of a test transistor; and etching the dielectric layer and the first polysilicon layer of the cell region to form a floating gate.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1A to 1F are cross-sectional views showing process steps of a method of fabricating flash memory device having a SAFG according to an embodiment of the invention.

### DETAILED DESCRIPTION

In the following detailed description, only certain exemplary embodiments of the invention are shown and described simply by way of illustration. As those skilled in the art will realize, the described embodiments may be modified in various ways, all without departing from the spirit or scope of the invention. Accordingly, the drawings and description are to be regarded as illustrative in nature and not restrictive. Like reference numerals designate like elements throughout.

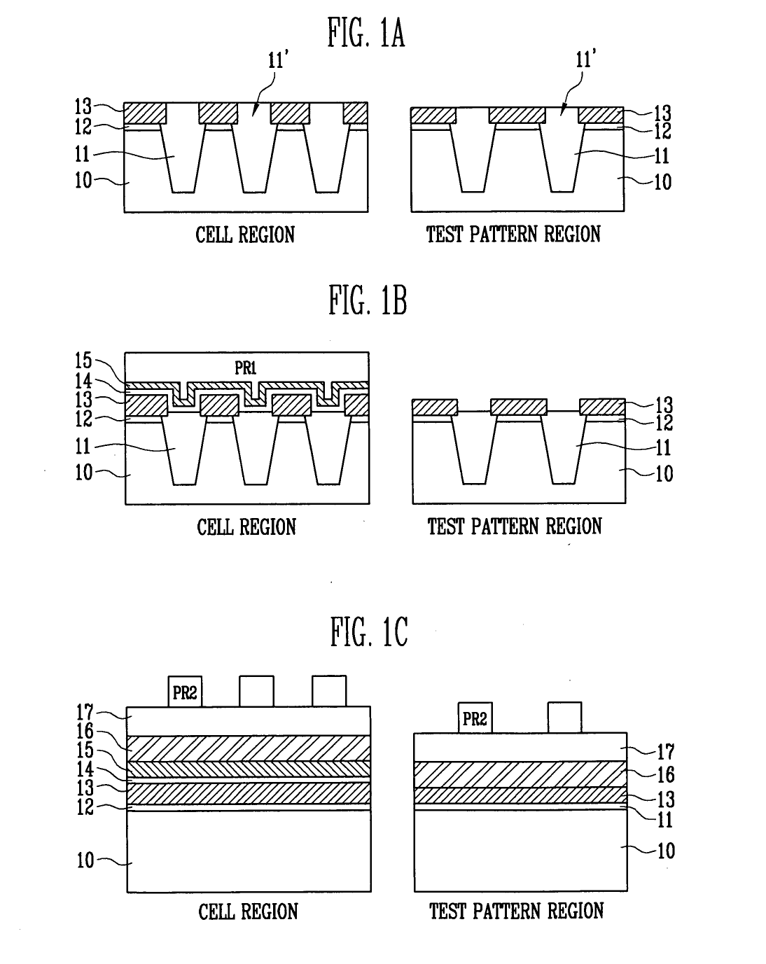

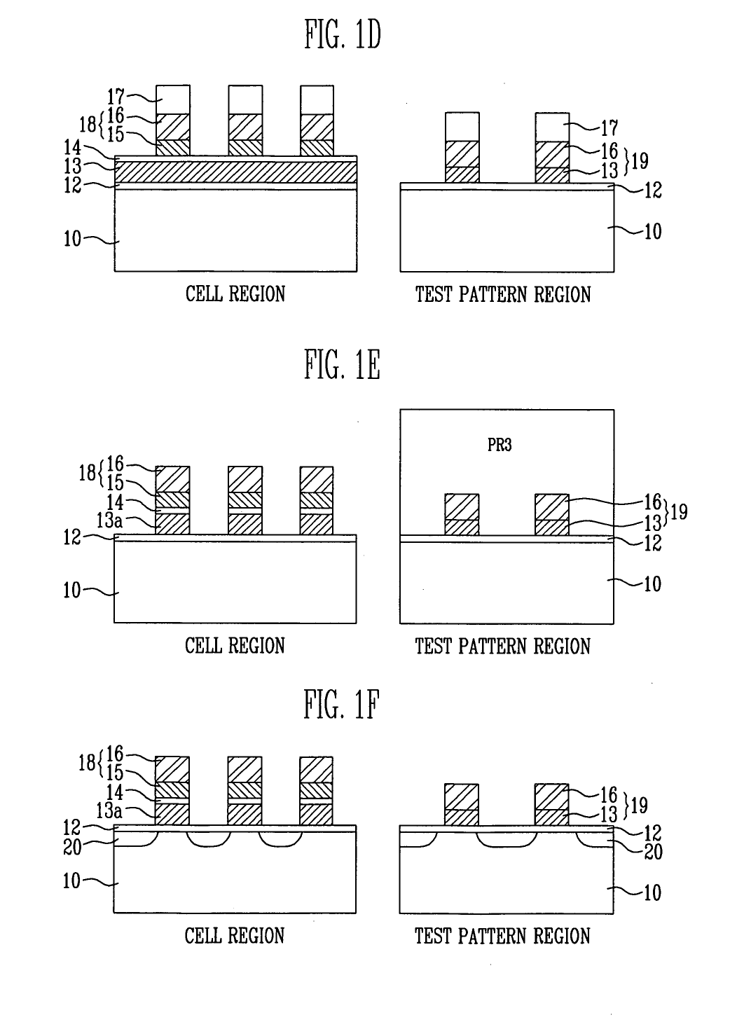

FIGS. 1A to 1F are cross-sectional views showing process steps of a method of fabricating flash memory device having an SAFG according to an embodiment of the invention. FIGS. 1A and 1B show the process steps in a word line direction and FIGS. 1C to 1F show the process steps in a bit line direction.

As shown in FIG. 1A, an isolation layer 11 is formed in a semiconductor substrate 10 having a cell region and a test pattern region, defining an active region. A tunnel oxide layer 12 is formed on the semiconductor substrate 10 of the active region. A first polysilicon layer 13 is formed on the tunnel oxide layer 12 in a self-aligned way to the isolation layer 11.

In other words, a screen oxide layer (not shown) and a pad nitride layer (not shown) are sequentially formed on the semiconductor substrate 10. The pad nitride layer and the screen oxide layer are selectively etched by a photolithography process in order to expose the semiconductor substrate 10. The exposed semiconductor substrate 10 is etched to form trenches.

A High Density Plasma (HDP) oxide layer is then deposited to bury the trenches. A polishing process is performed on the HDP oxide layer so that the pad nitride layer is exposed, thereby forming the isolation layer 11.

Thereafter, the pad nitride layer and the screen oxide layer are stripped and a pre-cleaning process is then implemented. Through the removal of the pad nitride layer and the screen oxide layer, a nipple 11′ on the isolation layer 11 is exposed. In the pre-cleaning process, the nipple 11′ is removed to a predetermined thickness and the critical dimension of the nipple 11′ is reduced accordingly.

The tunnel oxide layer 12 is formed on the semiconductor substrate 10 that is exposed through the removal of the pad nitride layer and the screen oxide layer. A polysilicon layer is deposited on the entire surface. A polishing process is then performed on the polysilicon layer so that the nipple 11′ is exposed, thereby forming the first polysilicon layer 13 which has regions 13′ separated from each other with the nipple 11′ therebetween.

As shown in FIG. 1B, the height of the nipple located between the first polysilicon layer 13 is lowered in order to secure the coupling ratio. An ONO layer is deposited on the entire structure along the surface step, forming a dielectric layer 14. A capping polysilicon layer 15 is formed on the dielectric layer 14.

A first photoresist PR1 is coated on the entire surface. The first photoresist PR1 is patterned using an exposure and development process so that a test pattern region is exposed. Though not shown in the drawings, the first photoresist PR1 may be patterned so that a region in which a peri transistor and a select transistor will be formed is also opened.

The capping polysilicon layer 15 is etched using the patterned first photoresist PR1 as an etch mask. The first photoresist PR1 is stripped and the dielectric layer 14 is then stripped by a wet etch process using the etched capping polysilicon layer 15 as an etch mask.

When etching the dielectric layer 14, a dry etch process may be used instead of the wet etch process. In the case where the dry etch process is employed, the capping polysilicon layer 15 is etched using the first photoresist PR1 as an etch mask. In a state where the first photoresist PR1 is not removed, the dielectric layer 14 are etched using a dry etch process and the first photoresist PR1 is removed.

As shown in FIG. 1C, a second polysilicon layer 16 and a nitride layer hard mask 17 are sequentially formed on the entire surface. A second photoresist PR2 that defines a control gate formation region in which the control gate will be formed is formed on the nitride layer 17.

The nitride layer 17 is etched using the second photoresist PR2 as an etch barrier. As shown in FIG. 1D, the second polysilicon layer 16, the capping polysilicon layer 15 and the first polysilicon layer 13 are etched using the dielectric layer 14 in the cell region and the tunnel oxide layer 12 in the test pattern region as etch stop layers while using the etched nitride layer 17 as an etch barrier with the second photoresist PR2 being stripped, thereby forming a control gate 18 having the capping polysilicon layer 15 and the second polysilicon layer 16, on the cell region and a gate 19 of a test transistor having the first polysilicon layer 13 and the second polysilicon layer 16, on the test pattern region.

Therefore, the gate of the test transistor 19 has a structure in which the second polysilicon layer 16 is stacked on the first polysilicon layer 13. Accordingly, although the first polysilicon layer 13 is separated from the field region, bias of a floating gate of a selected can be directly transferred to the first polysilicon layer 13 of the test transistor through the second polysilicon layer 16. It is thus possible to analyze a cell characteristic.

As shown in FIG. 1E, a third photoresist PR3 covering regions other than the cell region is formed in order to prevent the attack of the substrate against regions other than the cell region in a subsequent self-aligned etch (SAE) process.

Thereafter, the exposed dielectric layer 14 on the cell region is etched through the SAE process. The first polysilicon layer 13 is etched to form a floating gate 13a in the cell region.

As shown in FIG. IF, the third photoresist PR3 is stripped. An impurity ion is implanted using the control gate 18 and the gate of the test transistor 19 as masks, thus forming a source and drain junction 20

The fabrication of the flash memory device having SAFG according to an embodiment of the invention is thereby completed.

As described above, the invention has the following advantages.

Since the test transistor can be formed in the SAFG scheme, the intrinsic property of a cell can be analyzed.

Furthermore, since cell characteristics can be analyzed, it can contribute to the improvements of device characteristics.

While the invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of fabricating a flash memory device having a self-aligned floating gate (SAFG), the method comprising the steps of:
(a) forming an isolation layer in a semiconductor substrate having a cell region and a test pattern region, defining an active region, and forming a first polysilicon layer, which is self-aligned with the isolation layer, on the active region with the tunnel oxide layer interposed therebetween;
(b) forming a dielectric layer and a capping polysilicon layer on the entire surface;
(c) stripping the capping polysilicon layer and the dielectric layer formed on the test pattern region;
(d) forming a second polysilicon layer on the entire surface;
(e) etching the second polysilicon layer and the capping polysilicon layer formed in the cell region using a control gate etch mask, forming a control gate, and etching the second polysilicon layer and the first polysilicon layer formed in the test pattern region, forming a gate of a test transistor; and
(f) etching the dielectric layer and the first polysilicon layer of the cell region to form a floating gate.

2. The method as claimed in claim 1, wherein step (a) comprises the steps of:
forming a screen oxide layer and a pad nitride layer in the semiconductor substrate;
selectively etching the pad nitride layer, the screen oxide layer, and the semiconductor substrate to form a trench;
forming an isolation layer within the trench to define an active region;
stripping the pad nitride layer and the screen oxide layer to expose the semiconductor substrate of the active region;
reducing the height of the isolation layer, which protrudes due to the removal of the pad nitride layer and the screen oxide layer, using a pre-cleaning process;
forming a tunnel oxide layer on the active region; and
depositing a polysilicon layer on the entire surface and performing a polishing process to expose the isolation layer, thereby forming a first polysilicon layer self-aligned with the isolation layer.

3. The method as claimed in claim 1, wherein step (c) comprises the steps of:
forming a mask through which the test pattern region is opened;
dry-etching the capping polysilicon layer and the dielectric layer using the mask as an etch barrier; and
stripping the mask.

4. The method as claimed in claim 1, wherein step (c) comprises the steps of:
forming a mask through which the test pattern region is opened;
etching the capping polysilicon layer using the mask as an etch barrier;
stripping the mask; and
wet-etching the dielectric layer using the etched capping polysilicon layer as an etch barrier.
